(19) United States
(12) Patent Application Publication
(10) Pub. No.: US 2023/0170029 A1
(43) Pub. Date: Jun. 1, 2023

(54) PROGRAMMABLE DELAYS AND METHODS THEREOF

(71) Applicant: Ferroelectric Memory GmbH, Dresden (DE)

(72) Inventor: Stefano SIVERO, Comun Nuovo (BG) (IT)

(21) Appl. No.: 17/536,836

(22) Filed: Nov. 29, 2021

(51) Int. Cl. G11C 16/32; G11C 16/10; G11C 16/26; G11C 16/30

(52) U.S. Cl. CPC G11C 16/32; G11C 16/26; G11C 16/30; G11C 16/102

(57) ABSTRACT

Disclosed herein is a programmable delay circuit for providing an adjustable delay for a signal transmitted from an input node to an output node. The adjustable delay circuit includes a state-programmable memory element that may be programmed to a first state to provide a first delay as the adjustable delay or programmed to a second state to provide a second delay as the adjustable delay. The state-programmable memory element may be a remanent polarizable capacitor that may be programmed to at least two different remanent polarization states to configure the first delay or the second delay.

### TECHNICAL FIELD

Various aspects are related to circuits, and in particular, to programmable delays for analog and digital circuits and methods thereof, e.g., a method of operating a programmable delay circuit.

### BACKGROUND

Delays are widely used in both analog circuits and digital circuits to delay a signal. In general, a delay circuit receives an applied signal as an input and transmits the applied signal to the output with a time delay. Often, the time delay between input and output may need to be adjusted (e.g., trimmed) in order to adapt the delay time for the particular application or as conditions change. Typically, to achieve different delay times, a set of dedicated resources (e.g., additional chip real-estate for dedicated transistors, capacitors, silicon area, control signal routing, and/or metal) are required for each different delay time that may be selected. As a result, providing an adjustable delay may be costly, especially from the perspective of otherwise scarce on-chip resources.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects of the invention are described with reference to the following drawings, in which:

FIG. 1 shows a programmable delay circuit in a schematic view, according to various aspects;

FIG. 2 shows in schematic view a programmable delay circuit that includes an adjustment circuit and control circuit, according to various aspects;

FIG. 3 shows in schematic view a programmable delay circuit, according to various aspects;

FIG. 4 shows in schematic view a programmable delay circuit that includes an adjustment circuit and control circuit, according to various aspects;

FIG. 5 shows a state diagram of a state-programmable memory element that may be used in a programmable delay circuit, according to various aspects;

FIG. 6 shows a timing diagram of a programmable delay circuit, according to various aspects;

FIGS. 7a-7d show state diagrams for a state-programmable memory element that may be programmed for a programmable delay circuit, according to various aspects;

FIG. 8 shows a timing diagram of a programmable delay circuit, according to various aspects;

FIGS. 9a-9c show state diagrams for a state-programmable memory element that may be programmed for a programmable delay circuit, according to various aspects;

FIG. 10 shows in schematic view a programmable delay circuit that includes an adjustment circuit and control circuit, according to various aspects;

FIG. 11 shows in schematic view a programmable delay circuit that includes an adjustment circuit and control circuit, according to various aspects;

FIG. 12 shows a timing diagram of a programmable delay circuit, according to various aspects; and

FIG. 13 depicts an exemplary schematic flow diagram of a method for operating a programmable delay circuit.

### DESCRIPTION

The following detailed description refers to the accompanying drawings that show, by way of illustration, specific details and aspects in which the invention may be practiced. These aspects are described in sufficient detail to enable those skilled in the art to practice the invention. Other aspects may be utilized and structural, logical, and electrical changes may be made without departing from the scope of the invention. The various aspects are not necessarily mutually exclusive, as some aspects may be combined with one or more other aspects to form new aspects. Various aspects are described in connection with methods and various aspects are described in connection with devices (e.g., a regulator circuit, a memory circuit, or a system including a regulator circuit and an array of memory cells). However, it may be understood that aspects described in connection with methods may similarly apply to the devices, and vice versa.

In general, a delay circuit receives an applied signal at an input and transmits the applied signal to the output with a time delay. To provide an adjustable time delay (i.e. trimmable), prior solutions typically required a set of dedicated resources (e.g., additional chip real-estate for dedicated transistors, capacitors, area, control signal routing, and/or metal) for each different delay time that may be provided. As a result, providing an adjustable delay may be costly, especially from the perspective of on-chip resources. By contrast, the programmable delay circuit described in more detail below may provide a programmable delay without the need for additional chip-resources for the dedicated transistors, capacitors (which may cost area and/or control signal routing), or even metal options (which require a new mask set) for each selectable delay. The programmable delay circuit described below may include a state-programmable memory element (e.g., a remanent polarizable capacitor (e.g., a ferroelectric capacitor)) that may have a dynamic capacitance that depends on the programmed polarization state of the state-programmable memory element. As the voltage across the remanent polarizable capacitor is varied, the different dynamic capacitances for the various programmed polarization states may be associated with different delays. A polarization capability of a state-programmable memory element (e.g., remanent polarization capability, e.g., non-remanent spontaneous polarization capability) may be analyzed using capacity measurements (e.g., a spectroscopy), e.g., via a static (C-V) and/or time-resolved measurement or by polarization-voltage (P-V) or positive-up-negative-down (PUND) measurements. Another method for determining a polarization capability of a state-programmable memory element may include transmission electron microscopy, e.g., an electric-field dependent transmission electron microscopy.

The programmable delay circuit described below may be advantageous because it may be integrated directly into the logic circuit or analog circuit for which the delay is being provided. The programmable delay circuit described below may also be advantageous because the delay may be programmed to two or more different delay times while using fewer components.

The term “voltage” may be used herein with respect to “a supply voltage”, “an input voltage,” “an output voltage,” and the like. As an example, the term “supply voltage” may be used herein to denote a voltage provided to a circuit for operating the circuit components (e.g., for operating the logic components of a logic circuit). As another example, the “input voltage” may be the voltage level at an input node of circuit and the “output voltage” may be the voltage level at an output node of a circuit. The “voltage across” a component may be used herein to denote a voltage drop from a node on one side of a component (e.g., one side of a capacitor) to a node on the other side of the component (e.g., the other side of the capacitor).

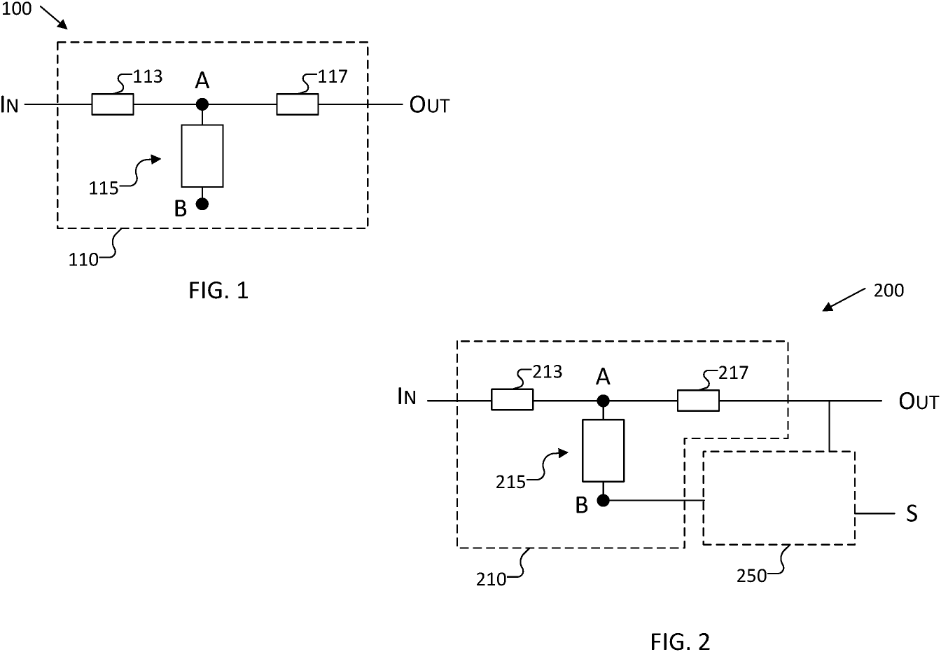

FIG. 1 shows a programmable delay circuit 100 for providing an adjustable delay. Circuit 100 may provide a delay to a signal applied to the input (e.g., “IN”) by transmitting it to the output node (e.g., “OUT”) after a time delay. To provide different time delays, circuit 100 may include an adjustable delay circuit 110 that includes a state-programmable memory element 115 with a dynamic capacitance. The dynamic capacitance of the state-programmable memory element 115 may be programmed using various programming states (e.g. a polarization state), where, depending on the programmed polarization state and the voltage across the state-programmable memory element 115, the adjustable delay circuit may provide a different delay time associated with the state-programmable memory element 115. The adjustable delay circuit 110 may also include any number of other elements (e.g., element 113 and/or element 117) that work in combination with the state-programmable memory element 115 to provide the overall delay time between the input node and the output node. The delay time of circuit 100 may be a function of the programmed state of the state-programmable memory element 115 and the voltage across the state-programmable memory element 115. In addition, the voltage across the state-programmable memory element 115 may be used to program the programming state of the state-programmable memory element 115.

FIG. 2 shows a programmable delay circuit 200 for providing an adjustable delay to a signal applied to the input (e.g., “IN”) by transmitting it to the output node (e.g., “OUT”) after a time delay. Programmable delay circuit 200 may be an exemplary embodiment of the programmable delay circuit 100 described above with respect to FIG. 1, and this example of FIG. 2 is not intended to limit adjustable delay circuit 100, which may be implemented in any number of ways. Programmable delay circuit 200 may include an adjustable delay circuit 210 and a control circuit 250. Adjustable delay circuit 210 may be an exemplary embodiment of the adjustable delay circuit 110 described above with respect to FIG. 1, and this example of FIG. 2 is not intended to limit adjustable delay circuit 110, which may be implemented in any number of ways. Programmable delay circuit 200 may include a state-programmable memory element 215 and a control circuit 250. State-programmable memory element 215 may be an exemplary embodiment of the state-programmable memory element 115 described above with respect to FIG. 1, and this example of FIG. 2 is not intended to limit state-programmable memory element 115, which may be implemented in any number of ways. In addition, adjustable delay circuit 210 may also include any number of other elements (e.g., element 213 and/or element 217) that work in combination with the state-programmable memory element 215 to provide the overall delay between the input node and the output node.

Control circuit 250 may be used to set the voltage across the state-programmable memory element 215. For example, an output voltage of control circuit 250 (e.g., a control signal) may connect to a node of the state-programmable memory element 215 (e.g., node B shown in FIG. 2) in order to influence the voltage across the state-programmable memory element 215 (e.g., the voltage between node A and node B (V_{AB})). If the voltage across the state-programmable memory element 215 is set to a first threshold programming voltage, the state-programmable memory element 215 may be programmed to a first programming state (e.g. a first polarization state). If the voltage across the state-programmable memory element 215 is set to a second threshold programming voltage, the state-programmable memory element 215 may be programmed to a second programming state (e.g., a second polarization state). In this manner, the control signal output from the control circuit 250 may assist in programming the programming state of the state-programmable memory element 215.

Control circuit 250 may receive any number of inputs, including for example, a selection signal (e.g., selection signal S), and the output voltage of control circuit 250 (e.g., the control signal provided to node B of the state-programmable memory element) may be based on the received selection signal. In other words, the control signal output from control circuit 250 may be a function of the selection signal. As another example, the control circuit 250 may be connected to the output node (e.g., OUT) of the programmable delay circuit 100. As with the selection signal, the control signal output from control circuit 250 may be based on (e.g., be a function of) the voltage provided from the output node. In this manner, the control signal output voltage from control circuit 250 may be influenced by the selection signal S and/or the output node of the programmable delay circuit 200.

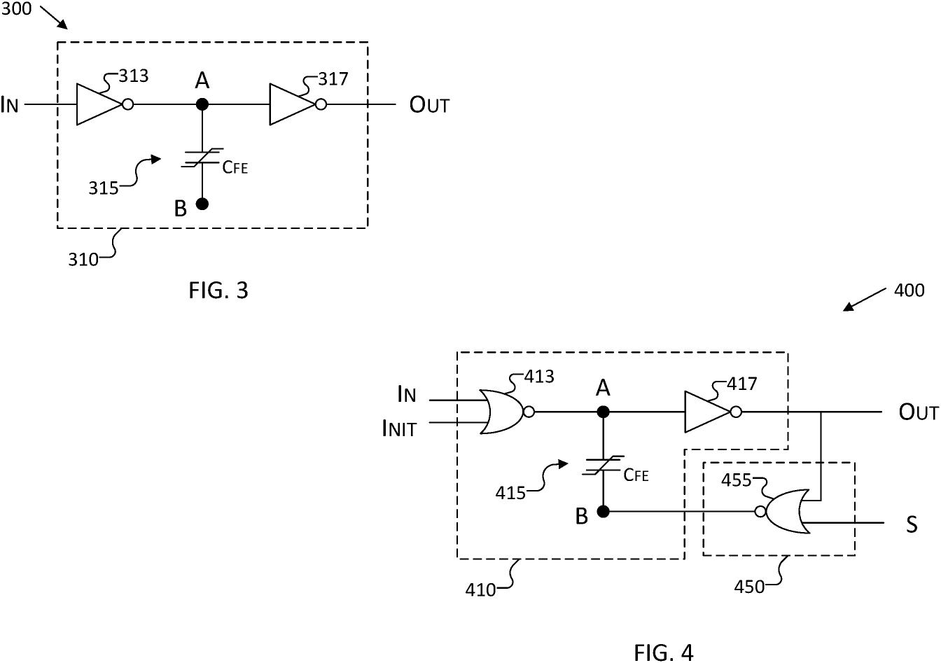

FIG. 3 shows a programmable delay circuit 300 for providing an adjustable delay. Programmable delay circuit 300 may be an exemplary embodiment of the programmable delay circuit 100 and/or 200 described above with respect to FIGS. 1 and 2, though this example in FIG. 3 is not intended to limit adjustable delay circuits 100 or 200, which may be implemented in any number of ways. Programmable delay circuit 300 may include an adjustable delay circuit 310. Adjustable delay circuit 310 may be an exemplary embodiment of the adjustable delay circuit 110 and/or 210 described above with respect to FIGS. 1 and 2, and this example in FIG. 3 is not intended to limit adjustable delay circuit 110 or 210, which may be implemented in any number of ways. Programmable delay circuit 300 may include a state-programmable memory element 315. State-programmable memory element 315 may be an exemplary embodiment of the state-programmable memory elements 115 and/or 215 described above with respect to FIGS. 1 and 2, and this example in FIG. 3 is not intended to limit state-programmable memory elements 115 or 215, which may be implemented in any number of ways. State-programmable memory element 315 may be, for example, a remanent polarizable capacitor that may be programmed to various polarization states (e.g., programming state), where, depending on the starting polarization state and the voltage across the remanent polarizable capacitor, each polarization state may be associated with a different delay time for the adjustable delay circuit. In addition, adjustable delay circuit 310 may also include any number of other elements (e.g., inverters 313 and 317) that work in combination with the state-programmable memory element 315 to provide the overall delay between the input node and the output node.

FIG. 4 shows a programmable delay circuit 400 for providing an adjustable delay. Programmable delay circuit 400 may be an exemplary embodiment of the programmable delay circuit 100, 200, and/or 300 described above with respect to FIGS. 1 to 3, and this example in FIG. 4 is not intended to limit adjustable delay circuit 100, 200, or 300, which may be implemented in any number of ways. Programmable delay circuit 400 may include an adjustable delay circuit 410 and a control circuit 450. Adjustable delay circuit 410 may be an exemplary embodiment of the adjustable delay circuit 110, 210, and/or 310 described above with respect to FIGS. 1 to 3, and this example of FIG. 4 is not intended to limit adjustable delay circuit 110, 210, or 310, which may be implemented in any number of ways. Programmable delay circuit 400 may include a state-programmable memory element 415 and a control circuit 450. State-programmable memory element 415 may be an exemplary embodiment of the state-programmable memory element 115, 215, and/or 315 described above with respect to FIGS. 1 to 3, and this example of FIG. 4 is not intended to limit state-programmable memory element 115, 215, or 315, which may be implemented in any number of ways. In addition, adjustable delay circuit 410 may also include any number of other elements (e.g., logic-NOR gate 413 and/or inverter 417) that work in combination with the state-programmable memory element 415 to provide the overall delay between the input node and the output node.

Control circuit 450 may be used to set the voltage across the state-programmable memory element 415. For example, an output voltage of control circuit 450 (e.g., a control signal) may connect to a node of the state-programmable memory element 415 (e.g., node B shown in FIG. 4) in order to influence the voltage across the state-programmable memory element 415 (e.g., the voltage drop from node A to node B (V_{AB})). If the voltage across the state-programmable memory element 415 is set to a first threshold programming voltage, the state-programmable memory element 415 may be programmed to a first programming state. If the voltage across the state-programmable memory element 415 is set to a second threshold programming voltage, the state-programmable memory element 415 may be programmed to a second programming state. In this manner, the control signal output from control circuit 450 may assist in programming the programming state of the state-programmable memory element 415.

Control circuit 450 may receive any number of inputs, including for example, a selection signal (e.g., selection signal S), and the output voltage of control circuit 450 (e.g., the control signal) may be based on the received signals. In other words, the control signal output from control circuit 450 may be a function of the received selection signal. As another example, the control circuit 450 may be connected to the output node (e.g., OUT) of the programmable delay circuit 400. As with the selection signal, the control signal output from control circuit 450 may be based on (e.g., be a function of) the voltage received from the output node. In this manner, the control signal output voltage from the control circuit 450 may be influenced by the selection signal S and/or the output node of the programmable delay circuit 400.

In the particular example shown in FIG. 4, the output node (“OUT”) of the programmable delay circuit 400 may be connected to one input port of a logic-NOR gate 455 and the selection signal S may be connected to another input port of a logic-NOR gate 455. The output node of the logic-NOR gate 455 may be provided as the control signal output of control circuit 450 to the adjustable delay circuit 410 (e.g., to node B of the state-programmable memory element 415). As should be appreciated, the control circuit 450 need not be limited to a logic-NOR gate, and other elements may be used to cause the control signal output voltage from control circuit 450 to be influenced by the selection signal S and/or the output node of the programmable delay circuit 400.

In addition, as will be discussed in more detail below, an initialization signal (e.g., “INIT”) may be provided to the programmable delay circuit 400 for initializing the adjustable control circuit to a particular programming state (e.g., a predefined programming state or a predefined polarization state). The initialization signal may be connected via a circuit element and may be used to influence the voltage across the state-programmable memory element 415 (e.g., the voltage drop from node A to B (V_{AB})). In the particular example shown in FIG. 4, the initialization signal may be connected to one input port of a logic-NOR gate 413 and the input node of programmable delay circuit 400 may be connected to another input port of logic-NOR gate 413. The output node of the logic-NOR gate 413 may be provided to a node of the state-programmable memory element 415 (e.g., node A). As should be appreciated, the circuit element connecting the initialization signal and/or input node to the state-programmable memory element 415 need not be limited to logic-NOR gate 413, and other elements may be used to connect the initialization signal and/or input node to the state-programmable memory element 415.

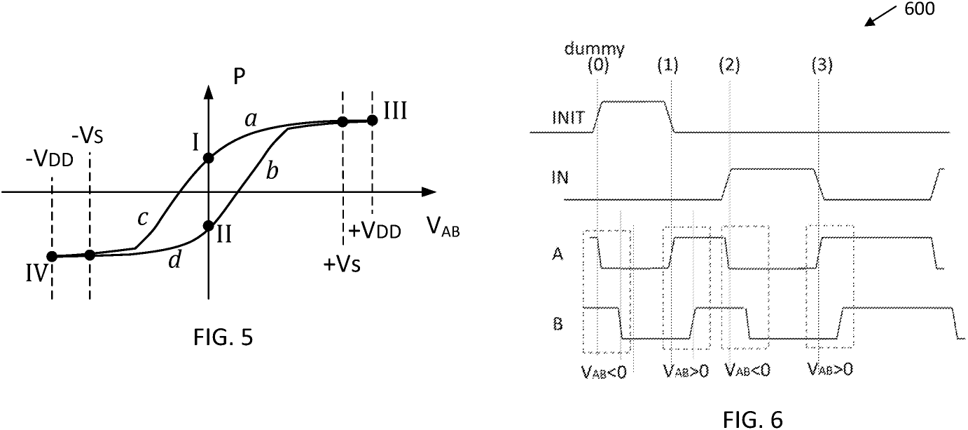

FIG. 5 shows a state diagram of a state-programmable memory element that may be used in a programmable delay circuit (e.g., programmable delay circuit 100, 200, 300, and/or 400). The programming (P) is plotted on the Y-axis as a function of the voltage across the state-programmable memory element (e.g., using FIG. 1 as an example, the voltage drop from node A to node B of state-programmable memory element 110 (V_{AB})) on the X-axis. In the case where the state-programmable memory element is a remanent polarizable capacitor (as shown, e.g., in FIGS. 3 and 4), the Y-axis may be understood as the polarization (P) of the remanent polarizable capacitor, and as used herein, programming states may be referred to and used interchangeably with, without limitation, remanent polarization states. Various polarization states have been identified on FIG. 5 with roman numerals I, II, III, and IV. As shown in FIG. 5, polarization states I and II may be understood as different remanent polarization states that remain after the voltage across the state-programmable memory element (V_{AB}) has returned to zero. Polarization state I may be understood as a positive remanent polarization state (e.g., programmed when a positive threshold voltage is applied) and polarization state II may be understood as a negative remanent polarization state (e.g., programmed when a negative threshold voltage is applied). In order to program the remanent polarization state, it should be appreciated that the threshold voltage needed to program the remanent polarization state (e.g., a positive threshold voltage or a negative threshold voltage) may be greater than a coercivity voltage (e.g., a positive coercivity voltage or a negative coercivity voltage) of the remanent polarizable capacitor.

As should also be appreciated from FIG. 5, the remanent polarization states (e.g., states I and/or II) may be programmed to a desired remanent polarization state value that is associated with a threshold voltage (applied across the state-programmable memory element) need to program the desired remanent polarization state value. In this sense, the threshold voltage may be understood as a switching voltage sufficient to program the remanent polarization state to this desired remanent polarization state value. In addition, the state-programmable memory element may also have a maximum remanent polarization to which the state-programmable memory element may be programmed. When the voltage across the state-programmable memory element exceeds the threshold voltage needed for programming the maximum remanent polarization, the state-programmable memory element will be programmed to the maximum positive remanent polarization state. With reference to FIG. 5, if state I were the maximum positive remanent polarization and +Vs were the threshold voltage need to program the state-programmable memory element to state I, a voltage of +V_{DD} applied across the state-programmable memory element would program the state-programmable memory element to the maximum positive remanent polarization associated with state I because +V_{DD} exceeds the maximum positive threshold voltage +V_{S}. Likewise, if state II were the maximum negative remanent polarization and -Vs were the threshold voltage need to program the state-programmable memory element to state II, a voltage of -V_{DD} applied across the state-programmable memory element would program the state-programmable memory element to the maximum negative remanent polarization associated with state II because -V_{DD} exceeds the maximum negative threshold voltage -V_{S}.

Referring to FIG. 5, polarization states III and IV may be understood as different polarization states (e.g., non-remanent polarization states) that may be achieved while the corresponding voltage across the state-programmable memory element (V_{AB}) is applied. For example, polarization state III may be achieved while the voltage level +V_{DD} is across the state-programmable memory element (V_{AB}), whereas polarization state IV may be achieved while the voltage level -V_{DD} is across the state-programmable memory element (V_{AB}). Once the voltage level across the state-programmable memory element (V_{AB}) returns to zero, the state-programmable memory element will return to its currently programmed remanent polarization state.

The voltage across the state-programmable memory element (V_{AB}) associated with states III and IV may be selected to ensure the state-programmable memory element is programmed to the desired remanent polarization state after V_{AB} returns to zero. Referring, for example, to FIG. 5, the voltage across the state-programmable memory element (V_{AB}) associated with polarization states III and IV may correspond to a voltage that exceeds the threshold voltage needed to program the state-programmable memory element to the desired remanent polarization states I and II. Thus, polarization state III may be associated with a positive threshold voltage (e.g., a switching voltage that exceeds the positive coercivity voltage and programs the state-programmable memory element to the desired positive remanent polarization state I). And polarization state IV may be associated with a negative threshold voltage (e.g., a switching voltage that exceeds the negative coercivity voltage and programs the state-programmable memory element to the desired negative remanent polarization state II). For example, if-V_{DD} exceeds the negative threshold voltage associated with negative remanent polarization state II, after -V_{DD} is applied, state-programmable memory element will be programmed to the negative remanent polarization state II, and the state-programmable memory element will return to remanent polarization state II when the voltage across the state-programmable memory element returns to zero. For example, if +V_{DD} exceeds the positive threshold voltage associated with positive remanent polarization state I, after +V_{DD} is applied, the state-programmable memory element will be programmed to the positive remanent polarization state I and the state-programmable memory element will return to remanent polarization state I when the voltage across the state-programmable memory element returns to zero.

Also shown in FIG. 5 are the transition paths (e.g., transmission paths a, b, c, and d) that may be followed when the voltage across the state-programmable memory element changes such that the state-programmable memory element changes from one polarization state to a different polarization state. Each transition path (e.g., a, b, c, and d) may be associated with a different dynamic capacitance of the state-programmable memory element, and accordingly, its associated delay time. For example, transition paths a and d may be associated with a low capacitance and a short delay time while transition paths c and b may be associated with a high capacitance and a long delay time. As depicted in FIG. 5, for example, transition path a may be associated with a transition from polarization state I to polarization state III (e.g., after +V_{DD} is applied to V_{AB}), or with a transition from polarization state III to polarization state I (e.g., after +V_{DD} is no longer applied and VAB returns to zero). Similarly, transition path d may be associated with a transition from polarization state II to polarization state IV (e.g., after -V_{DD} is applied to V_{AB}), or with a transition from polarization state IV to polarization state II (e.g., after -V_{DD} is no longer applied, and V_{AB} returns to zero). As should be appreciated, when applying -V_{DD} from polarization state II or when applying +V_{DD} from polarization state I, regardless as to whether these voltages exceed the corresponding threshold voltage (e.g., -Vs or +Vs) of the state-programmable memory element, the state-programmable memory element will remain in (or be reprogrammed to) its previously-programmed polarization state.

Transition path b may be associated with a transition from polarization state II to polarization state III (e.g., after +V_{DD} is applied to V_{AB}). However, unlike transition paths a and d, the applied voltage (+V_{DD}) associated with the transition may also re-program (assuming +V_{DD} exceeds the positive threshold voltage associated with positive remanent polarization state I) the state-programmable memory element to a new polarization state (e.g., switching from the negative remanent polarization state II to the positive remanent polarization state I). As such, when +V_{DD} is no longer applied and V_{AB} returns to zero, the transition may not follow transition path b back to negative remanent polarization state II, but rather, transition path a back to newly-programmed positive remanent polarization state I. Transition path c may be associated with a transition from polarization state I to polarization state IV (e.g., after -V_{DD} is applied to VAB). Similar to transition path b, the applied voltage (-V_{DD}) associated with the transition may also re-program the polarization state to a new polarization state (e.g., switching from the positive remanent polarization state I to the negative remanent polarization state II). As such, when -V_{DD} is no longer applied and V_{AB} returns to zero, the transition may not follow transition path c back to positive remanent polarization state I, but rather, transition path d back to newly-programmed negative remanent polarization state II.

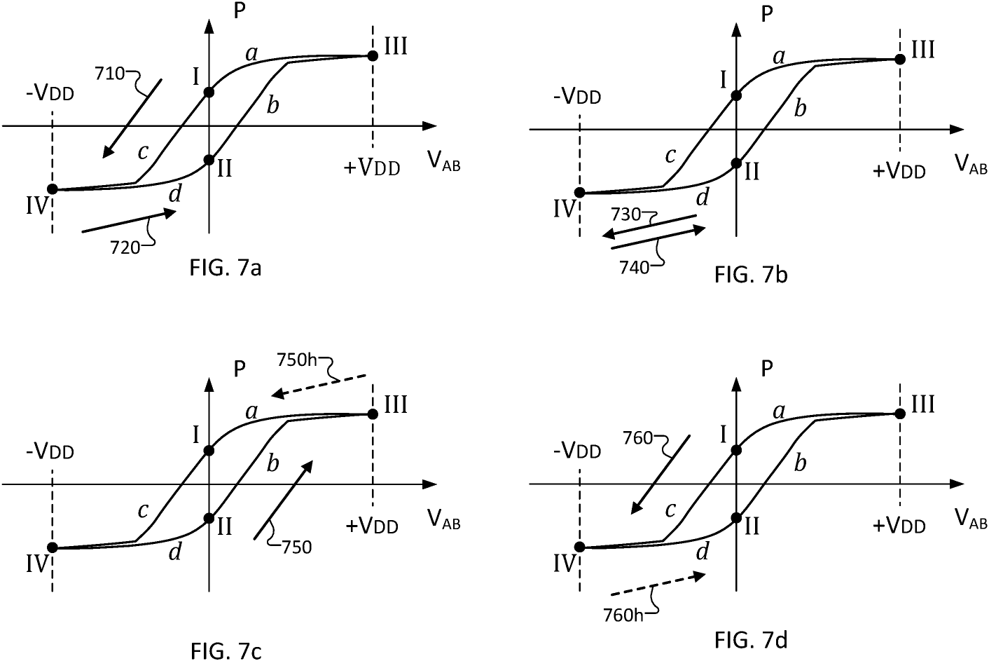

To better illustrate how the various programming states and voltages across the state-programmable memory element may impact the transition paths and delay timing, exemplary programmable delay circuit 400 will be described with reference to the timing diagram of FIG. 6 and the various state diagrams shown in FIGS. 7a-7d.

FIG. 6 shows an exemplary timing diagram 600 for programmable delay circuit 400. The timing diagram 600 shows exemplary voltage levels that may be applied to the input signal (“IN”) and the initialization signal (“INIT”) nodes of the programmable delay circuit 400 and adjustable delay circuit 410. Timing diagram 600 also shows the voltage level at each of nodes A and B on each side of the state-programable memory device 415. As depicted in the timing diagram of FIG. 6, a low voltage level may be understood to be zero volts while a high voltage level may be understood to be +V_{DD}, where +V_{DD} and -V_{DD} exceed the threshold voltage needed to program the respective remanent polarization state of the state-programable memory device 415. In addition, +V_{DD} may be understood as a logic level voltage (e.g., logic high) that may be provided as an input or output from logic elements (e.g., a logic-NOR gate) and zero volts may be understood as a logic low. As should be understood, these voltage levels are exemplary and other levels may be used.

The timings shown in diagram 600 may be associated with a first operating mode of the programmable delay circuit 400, which may be set when the received selection signal S is at a low voltage level. As should be appreciated from the Logic-NOR gate 455, while the selection signal S remains low, the control signal output to node B of the state-programmable memory element 415 is based on the voltage at the output node (“OUT”) of the programmable delay circuit 400 such that when the voltage at the output node is high, the voltage at node B will be low and when the voltage at the output node is low, the voltage at node B will be high. In other words, while the selection signal S remains low, node B follows node A with a certain delay due to logic gates (e.g., inverter 417 and NOR-logic gate 455). As will be apparent from the description below, when the programmable delay circuit 400 is in this first operating mode, the programmable delay circuit 400 may provide a long delay time that is associated with a high capacitance of the state-programmable memory element 415.

Because the state-programmable memory element 415 may be in an unknown state or undesirable state, an initialization signal may be used to set the state-programmable memory element 415 to a predefined state (e.g., to remanent polarization state II, as shown for example in FIG. 7a). This may be referred to as a “dummy” pulse for initializing the programmable delay circuit 400 to the predefined state. As can be seen at time “(0)” (also labeled “dummy”) in FIG. 6, the initialization signal may be driven high as the rising edge of a “dummy” pulse. This causes the voltage at node A of the state-programmable memory element 415 to fall to zero. As shown in FIG. 6, if the voltage at node B was high when the voltage at node A falls to zero, the voltage drop (V_{AB}) across the state-programmable memory element 415 will charge to -V_{DD} and, with reference to FIG. 7a and assuming the state-programmable memory element 415 is starting in remanent polarization state I, the state-programmable memory element 415 will transition to polarization state IV (along transition path c, denoted by arrow 710). Because -V_{DD} is below the negative threshold voltage, this will program the state-programable memory device 415 to the negative remanent polarization state, such that when the voltage across state-programable memory device 415 returns to zero, the state-programable memory device 415 will return to polarization state II. As noted above, because the selection signal S remains low, the voltage at node B of the state-programmable memory element 415 will follow node A with a certain delay due to logic gates (e.g., inverter 417 and NOR-logic gate 455) such that the voltage across the state-programmable memory element 415 (V_{AB}) returns to zero along transition path d, denoted by arrow 720 in FIG. 7a, to return to polarization state II.

The same result occurs, albeit via a different set transition paths, even if the state-programmable memory element 415 were starting instead in remanent polarization state II. In this case, when the initialization pulse is provided, the state-programmable memory element 415 will charge to -V_{DD} and transition from polarization state II to polarization state IV along transition path d, denoted by arrow 730 in FIG. 7b. Because -V_{DD} is below the negative threshold voltage associated with the negative remanent polarization state II, this will program the state-programable memory device 415 to the negative remanent polarization state, such that when the voltage across state-programable memory device 415 returns to zero, the state-programable memory device 415 will return to polarization state II along transition path d, denoted by arrow 740 in FIG. 7b. Thus, regardless of the initial remanent polarization state of the state-programmable memory element 415, it is now set to a predefined state (e.g., remanent polarization state II).

At the falling edge of the initialization “dummy” pulse, as seen at time “(1)” of FIG. 6, the low voltage of INIT causes the voltage at node A of the state-programmable memory element 415 to rise to high. Because the voltage at node B was low when the voltage at node A went high, the voltage drop (V_{AB}) across the state-programmable memory element 415 will charge to +V_{DD} and, with reference to FIG. 7c, the state-programmable memory element 415 will transition from polarization state II (along transition path b denoted by arrow 750) to polarization state III. Because +V_{DD} is above the positive threshold voltage associated with the positive remanent polarization state I, this will program the state-programable memory device 415 to the positive remanent polarization state, such that when the voltage across state-programable memory device 415 returns to zero, the state-programable memory device 415 will return to polarization state I. Because the selection signal S remains low, the voltage at node B will eventually follow node A, V_{AB} then returns to zero, and the state-programable memory device 415 returns (along path a denoted by arrow 750h) to polarization state I. To the extent the selection signal S remains low, the programable delay circuit 400 may provide a long delay time for the next transition of the input signal IN.

As seen at time “(2)” of FIG. 6, the next transition of the input signal is a rising edge when IN rises from low to high. This causes A to fall from high to low. Because B was high at the time A fell to low, the voltage across state-programable memory device 415 (V_{AB}) will charge to -V_{DD} along transition path c as shown in FIG. 7d with arrow 760, providing a long delay time that is associated with a high capacitance of the state-programmable memory element 415. Because -V_{DD} is below the negative threshold voltage associated with the negative remanent polarization state II, this will program the state-programable memory device 415 to the negative remanent polarization state, such that when the voltage across state-programable memory device 415 returns to zero, the state-programable memory device 415 will return to polarization state II. Because the selection signal S remains low, the voltage at node B will follow node A such that the voltage across the state-programmable memory element 415 (V_{AB}) returns to zero along transition path d, denoted by arrow 760h in FIG. 7d, to return to polarization state II. The transition path d denoted by arrow 760h may be thought of as a “hidden” transition that resets the polarization state of the state-programmable memory element 415 to a predefined state such that the next change in the input signal will also cause the state-programmable memory element 415 to follow a transition path associated with the high capacitance of the state-programmable memory element 415 to provide the long delay time. Accordingly, when the input signal falls from high to low, as shown in FIG. 6 at time “(3),” the next transition path will be from polarization state II to polarization state III along transition path b, as shown in FIG. 7c by arrow 750 (as discussed above with respect to time “(1)” of FIG. 6), and then state-programmable memory device 415 will return to polarization state I along “hidden” transition path a, as shown in FIG. 7c by arrow 750h.

As should be appreciated from the above-described timings and state-diagrams, to the extent the selection signal S remains low, the programable delay circuit 400 may continue to provide a long delay time for each subsequent transition of the input signal. When the input signal rises from low to high (e.g., on a rising edge), the state-programmable memory element 415 will transition from polarization state I to polarization state IV along transition path c, as shown in FIG. 7d by arrow 760, and return to polarization state II along hidden transition path d, as shown in FIG. 7d by arrow 760h. And when the input signal falls from high to low (e.g., on a falling edge), the state-programmable memory element 415 will transition from polarization state II to polarization state III along transition path b, as shown in FIG. 7c by arrow 750, and return to polarization state I along hidden transition path a, as shown in FIG. 7c by arrow 750h.

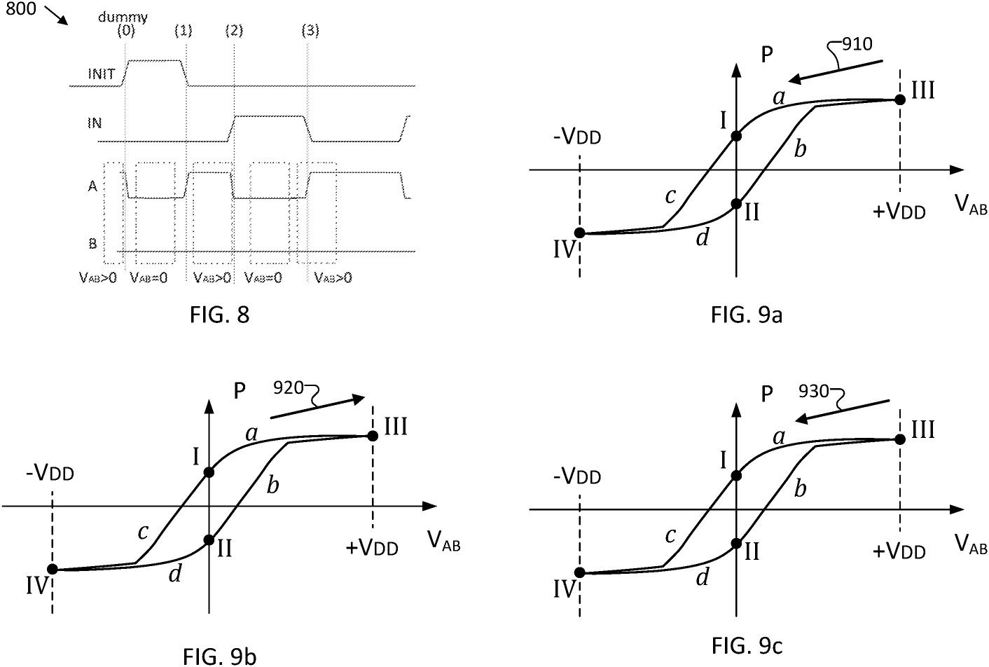

The programable delay circuit 400 may also be programmed to a second operating mode that provides a short delay time that is associated with a low capacitance of the state-programmable memory element 415. To better illustrate how the various programming states and the voltage across the state-programmable memory element may impact the transition paths and delay timing when in this second operating mode, exemplary programmable delay circuit 400 will be described with reference to the timing diagram of FIG. 8 and the various state diagrams shown in FIGS. 9a-9c.

The timings shown in diagram 800 may be associated with a second operating mode of the programmable delay circuit 400, which may be set when the received selection signal S is at a high voltage level. As should be appreciated from the Logic-NOR gate 455, while the selection signal S remains high, the control signal output to node B of the state-programmable memory element 415 is always set to zero. As will be apparent from the description below, when the programmable delay circuit 400 is in this second operating mode, the programmable delay circuit 400 may provide a short delay time that is associated with a low capacitance of the state-programmable memory element 415.

As with FIG. 6, timing diagram 800 of FIG. 8 shows exemplary voltage levels that may be at the various nodes of the programmable delay circuit 400, where a low voltage level may be understood to be zero volts while a high voltage level may be understood to be +VDD. Similarly, +VDD and -VDD may be understood to exceed the threshold voltage needed to program the state-programable memory device 415 to a corresponding remanent polarization state (e.g., to a positive remanent polarization state or a negative remanent polarization state).

As with the first operating mode, an initialization signal may be used to set the state-programmable memory element 415 to a known state (e.g., to set remanent polarization state I, as shown, for example, in FIG. 9a). This may be referred to as a “dummy” pulse for initializing the programmable delay circuit 400 while the input signal remains low. Before the “dummy” pulse, because the input signal remains low, the voltage at node A will be at +V_{DD} and the voltage at node B will be zero. Accordingly, the voltage across the state-programmable memory element 415 (V_{AB}) will be at +V_{DD}. Because +V_{DD} is above the positive threshold voltage associated with positive remanent polarization state I, this will program the state-programable memory device 415 to the positive remanent polarization state I. As can be seen at time “(0)” (also labeled “dummy”), the initialization signal may be driven high as the rising edge of a “dummy” pulse while the input remains low. This causes the voltage at node A of the state-programmable memory element 415 to fall from +V_{DD} to zero. As shown in FIG. 8, since the voltage at node B remains low, the voltage drop (V_{AB}) across the state-programmable memory element 415 will return from +V_{DD} to zero volts, and the state-programmable memory element 415 will return to its current remanent polarization state I.

Next, at the falling edge of the “dummy” pulse, as seen at time “(1)” of FIG. 9, the low voltage of INIT causes the voltage at node A of the state-programmable memory element 415 to rise to high while the voltage at node B remains low, providing a voltage drop (VAB) across the state-programmable memory element 415 that will charge to +V_{DD} and, with reference to FIG. 9b, the state-programmable memory element 415 will transition along transition path a (indicated by arrow 920) to polarization state III. Because +V_{DD} is above the positive threshold voltage associated with remanent polarization state I, this will program (or, reprogram) the state-programable memory device 415 to the positive remanent polarization state I, such that when the voltage across state-programable memory device 415 returns to zero, the state-programable memory device 415 will return to polarization state I. To the extent the selection signal S remains high, the programable delay circuit 400 may continue to provide a short delay time for each subsequent transition of the input signal IN.

For example, as seen at time “(2)” of FIG. 8, the next transition of the input signal is a rising edge when IN rises from low to high. This causes A to fall from high to low. Because the voltage across the state-programable memory device 415 was +V_{DD} (at polarization state III) and the voltage at node B is low, the voltage across state-programable memory device 415 (V_{AB}) will return to zero along transition path a, as shown in FIG. 9c by arrow 930, to polarization state I, providing a short delay time that is associated with a low capacitance of the state-programmable memory element 415. Next, when the input signal falls from high to low, as shown in FIG. 8 at time “(3),” the next transition path will be from polarization state I to polarization state III along transition path a, as shown in FIG. 9b by arrow 920.

As should be appreciated from the above-described timings and state diagrams, to the extent the selection signal S remains high, the programable delay circuit 400 may continue to provide a low delay time for each subsequent transition of the input signal as the state-programmable memory element 415 transitions from polarization state III to polarization state I (along transition path a) when the input signal rises from low to high (e.g., on a rising edge) and from polarization state I to polarization state III (along transition path a) when the input signal falls from high to low (e.g. on a falling edge).

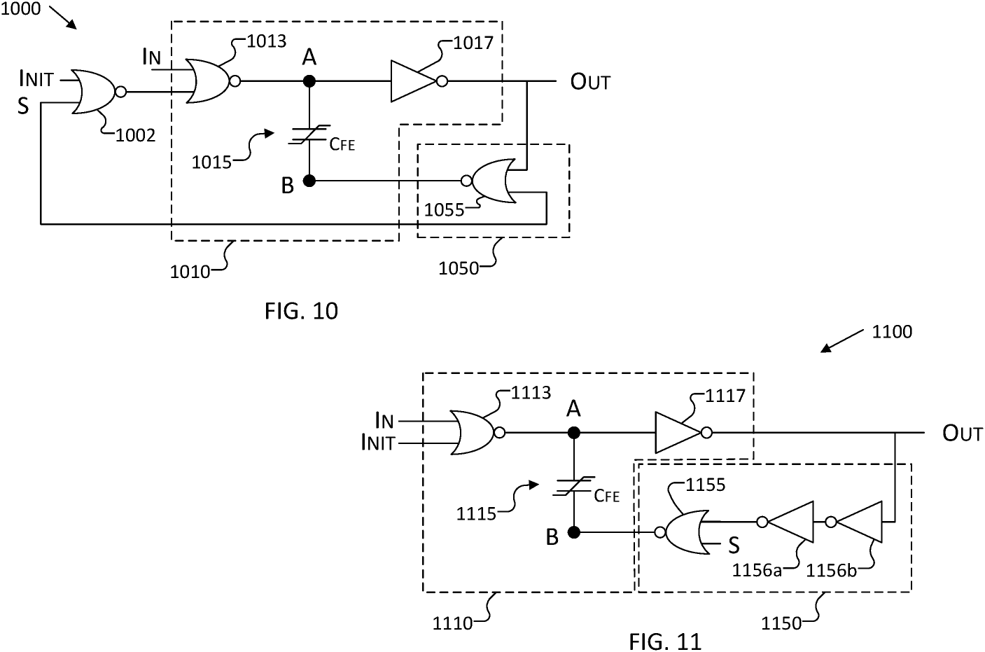

As should be appreciated from this design, the initialization signal may be unnecessary when the programmable delay circuit 400 is in the second operating mode (e.g., is providing a short delay time that is associated with a low capacitance of the state-programmable memory element 415). A programmable delay circuit that bypasses the initialization signal when operating in the second operating mode is shown in FIG. 10, as discussed in more detail below.

FIG. 10 shows a programmable delay circuit 1000 for providing an adjustable delay. Programmable delay circuit 1000 may be an exemplary embodiment of the programmable delay circuit 100, 200, 300, and/or 400 described above with respect to FIGS. 1 to 9, and this example in FIG. 10 is not intended to limit adjustable delay circuit 100, 200, 300, or 400, which may be implemented in any number of ways. Programmable delay circuit 1000 may include an adjustable delay circuit 1010 and a control circuit 1050. Without limitation, adjustable delay circuit 1010 may be an exemplary embodiment of the adjustable delay circuit 110, 210, 310, and/or 410 described above with respect to FIGS. 1 to 9. Programmable delay circuit 1000 may include a state-programmable memory element 1015 and a control circuit 1050. Without limitation, state-programmable memory element 1015 may be an exemplary embodiment of the state-programmable memory element 115, 215, 315, and/or 415 described above with respect to FIGS. 1 to 9. In addition, adjustable delay circuit 1010 may also include any number of other elements (e.g., logic-NOR gate 1013 and/or inverter 1017) that work in combination with the state-programmable memory element 1015 to provide the overall delay between the input node and the output node.

As noted with respect to programmable delay circuit 400, described above with respect to FIGS. 8-9, the initialization signal may be unnecessary when the programmable delay circuit 400 is in the second operating mode (e.g., is providing a short delay time that is associated with a low capacitance of the state-programmable memory element 415). Programmable delay circuit 1000 shows one such implementation of a bypass circuit (e.g., Logic-NOR gate 1002) that bypasses the initialization signal when operating in the second operating mode. The selection signal S may be connected to one input of the Logic-NOR gate 1002 and the initialization signal INIT to the other input of the Logic-NOR gate 1002. The output of Logic-NOR gate 1002 may then be connected to an input of Logic-NOR gate 1013 that has another input connected to the input signal. Such a configuration may be used to bypass the INIT signal (e.g., by keeping the output of Logic-NOR gate 1002 at low) when the selection signal S is high.

FIG. 11 shows a programmable delay circuit 1100 for providing an adjustable delay. Programmable delay circuit 1100 may be an exemplary embodiment of the programmable delay circuit 100, 200, 300, 400, and/or 1000 described above with respect to FIGS. 1 to 10, and this example in FIG. 11 is not intended to limit adjustable delay circuit 100, 200, 300, 400, or 1000, which may be implemented in any number of ways. Programmable delay circuit 1100 may include an adjustable delay circuit 1110 and a control circuit 1150. Without limitation, adjustable delay circuit 1110 may be an exemplary embodiment of the adjustable delay circuit 110, 210, 310, 410, and/or 1010 described above with respect to FIGS. 1 to 10. Programmable delay circuit 1100 may include a state-programmable memory element 1115 and a control circuit 1150. Without limitation, state-programmable memory element 1115 may be an exemplary embodiment of the state-programmable memory element 115, 215, 315, 415, and/or 1015 described above with respect to FIGS. 1 to 10. In addition, adjustable delay circuit 1110 may also include any number of other elements (e.g., logic-NOR gate 1113 and/or inverter 1117) that work in combination with the state-programmable memory element 1015 to provide the overall delay between the input node and the output node.

In addition, the control circuit 1150 may further include an additional delay element between the output node of programmable delay circuit 1100 and the input node of the logic-OR gate 1155 of the control circuit 1150. The additional delay element may delay the influence that the control signal from the control circuit 1150 (e.g., the voltage at the output node of control circuit 1150 ) may have on the voltage at node B of the state-programmable memory element 1115. As shown in FIG. 11, inverters 1156a and 1156b may be used to provide the additional delay time between the output node of programmable delay circuit 1100 and the input node of the logic-OR gate 1155 of the control circuit 1150. In other words, while the selection signal S remains low, node B follows node A with a certain delay due to inverter 1117 and NOR-logic gate 1155 and an additional delay time provided by inverters 1156a and 1156b. While two inverters 1156a and 1156b have been shown as providing the additional delay, this example is not intended to be limiting, and any type and number of logic element(s) may be used to provide the additional delay.

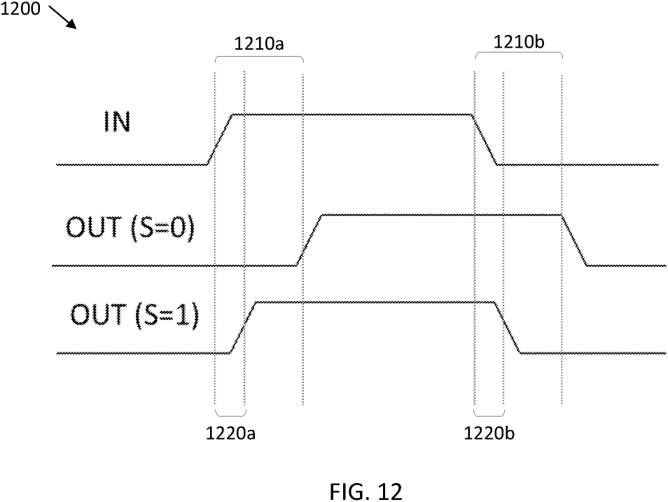

FIG. 12 shows an exemplary timing diagram 1200 associated with a programmable delay circuit that may be operated in two modes (e.g., optionally by a mode selection signal S). Without limitation, timing diagram 1200 may be the timing associated with programmable delay circuit 100, 200, 300, 400, 1000, and/or 1100 as discussed above with respect to FIGS. 1-4, 10, and 11. The timing diagram 1200 shows exemplary voltage levels that may be applied to the input signal (“IN”) and then the resulting output signal (“OUT”) that is provided at the output node of the programmable delay circuit. If a first mode is selected (e.g., when a mode selection signal S is set to a logic low voltage level (e.g., S=0)), the output is delayed by a long delay. As shown in FIG. 12, when in a first mode (e.g., S=0), after a rising edge of the input signal IN, the output signal OUT will follow after a long delay 1210a. Similarly, when in the first mode (e.g., S=0), after a falling edge of the input signal IN, the output signal OUT will follow after a long delay 1210b. If a second mode is selected (e.g., when the mode selection signal S is set to a logic high voltage level (e.g., S=1)), the output is delayed by a short delay. As shown in FIG. 12, when in a second mode (e.g., S=1), after a rising edge of the input signal IN, the output signal OUT will follow after a short delay 1220a. Similarly, when in the second mode (e.g., S=1), after a falling edge of the input signal IN, the output signal OUT will follow after a short delay 1220b.

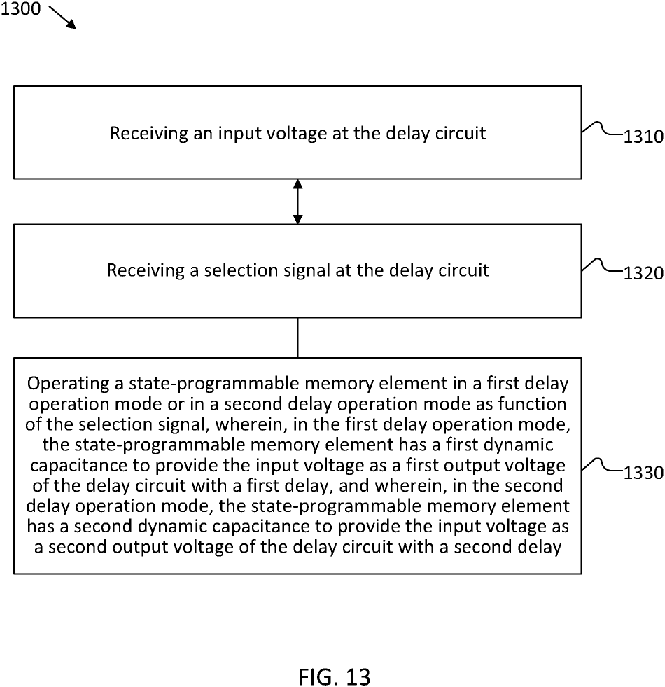

FIG. 13 depicts an exemplary schematic flow diagram 1300 of a method for operating a delay circuit. Method 1300 may implement any of the features and/or structures described above with respect to the programmable delay circuits described above with respect to FIGS. 1-12.

Method 1300 includes, in 1310, receiving an input voltage at the delay circuit. Method 1300 also includes, in 1320, receiving a selection signal at the delay circuit. Method 1300 also includes, in 1330, operating a state-programmable memory element in a first delay operation mode or in a second delay operation mode as function of the selection signal. In the first delay operation mode, the state-programmable memory element has a first dynamic capacitance to provide the input voltage as a first output voltage of the delay circuit with a first delay. In the second delay operation mode, the state-programmable memory element has a second dynamic capacitance to provide the input voltage as a second output voltage of the delay circuit with a second delay.

Method 1300 may also include that the first dynamic capacitance is associated with a first transition time for the state-programmable memory element to transition from a first initial state to a first subsequent state. Method 1300 may also include that the second dynamic capacitance is associated with a second transition time for the state-programmable memory element to transition from a second initial state to a second subsequent state. Method 1300 may also include that the first subsequent state is the same as the second subsequent state. Method 1300 may also include that the first initial state includes a positive remanent polarization state, and the first subsequent state includes a non-remanent positive polarization state and/or the first initial state includes the non-remanent positive polarization state and the first subsequent state includes the positive remanent polarization state.

Method 1300 may also include that the second initial state includes a negative remanent polarization state, and the second subsequent state includes a non-remanent positive polarization state and/or a the second initial state includes a positive remanent polarization state and the second subsequent state includes a non-remanent negative polarization state. Method 1300 may also include initializing the state-programmable memory element to a predetermined polarization state before operating the state-programmable memory element. Method 1300 may also include that the predetermined polarization state includes one of a positive remanent polarization state of the state-programmable memory element or a negative remanent polarization state of the state-programmable memory element.

In the following, various examples are provided that may include one or more aspects described above with reference to a programmable delay circuit (e.g., programmable delay circuit 100, 200, 300, 400, 1000, and/or 1100). It may be intended that aspects described in relation to the circuits may apply also to the described method(s), and vice versa.

Example 1 is a programmable delay circuit including an input node, an output node, and an adjustable delay circuit including a state-programmable memory element, wherein the adjustable delay circuit is connected between the input node and the output node and configured to provide an adjustable delay for a signal transmitted from the input node to the output node, wherein if the state-programmable memory element is programmed to a first state, the adjustable delay is a first delay and if the state-programmable memory element is programmed to a second state, the adjustable delay is a second delay.

Example 2 is the programmable delay circuit of example 1, wherein the first delay includes a first transition time for the state-programmable memory element to transition from the first state to a subsequent state, wherein the second delay includes a second transition time for the state-programmable memory element to transition from the second state to the subsequent state.

Example 3 in the programmable delay circuit of example 2, wherein the first transition time is different from the second transition time.

Example 4 is the programmable delay circuit of any one of examples 1 to 3, wherein the first delay is different from the second delay.

Example 5 is the programmable delay circuit of any one of examples 1 to 4, wherein the state-programmable memory element includes a remanent polarizable capacitor.

Example 6 is the programmable delay circuit of example 5, wherein the first state of the state-programmable memory element is defined by a first remanent polarization state of the remanent polarizable capacitor, wherein the second state of the state-programmable memory element is defined by a second remanent polarization state of the remanent polarizable capacitor, and wherein the subsequent state of the state-programmable memory element is defined by a further polarization state of the remanent polarizable capacitor.

Example 7 is the programmable delay circuit of example 6, wherein the further polarization state includes a non-remanent polarization state of the remanent polarizable capacitor defined by a non-zero voltage across the remanent polarizable capacitor.

Example 8 is the programmable delay circuit of example 7, wherein the non-zero voltage across the remanent polarizable capacitor is sufficient to program the remanent polarizable capacitor to at least one of the first remanent polarization state or the second remanent polarization state.

Example 9 is the programmable delay circuit of example 8, wherein the non-zero voltage across the remanent polarizable capacitor that is sufficient to program the remanent polarizable capacitor to at least one of the first remanent polarization state or the second remanent polarization state includes a threshold voltage of the remanent polarizable capacitor.

Example 10 is the programmable delay circuit of any one of examples 1 to 9, wherein the state-programmable memory element includes a remanent polarizable capacitor that is programmable to two distinct remanent polarization states as a function of a voltage across the remanent polarizable capacitor.

Example 11 is the programmable delay circuit of example 10, wherein the first state or the second state includes one of the two distinct remanent polarization states.

Example 12 is the programmable delay circuit of example 1, wherein the adjustable delay circuit is configured to program the state-programmable memory element to the first state or the second state based on a control signal provided to the adjustable delay circuit from a control circuit.

Example 13 is the programmable delay circuit of example 12, wherein the control signal is based on an output voltage at the output node.

Example 14 is the programmable delay circuit of any one of examples 12 to 13, wherein the control circuit is configured to provide the control signal to the adjustable delay circuit as a result of a logic-NOR operation with the output node and a selection signal provided to the control circuit.

Example 15 is the programmable delay circuit of any one of examples 13 to 14, wherein the control circuit further includes an additional delay element having an additional delay time, wherein the control circuit is configured to provide the control signal to the adjustable delay circuit after the additional delay time.

Example 16 is the programmable delay circuit of any one of examples 13 to 15, wherein the control circuit includes a logic-NOR gate, wherein the output node is connected to a first NOR input of the logic-NOR gate, wherein a second NOR input of the logic-NOR gate is configured to receive the selection signal, and wherein the control signal includes an output result of the logic-NOR gate defined by a logic-NOR operation of the first NOR input with the second NOR input.

Example 17 is the programmable delay circuit of any one of examples 1 to 16, further including an initialization circuit connected between the input node and the adjustable delay circuit configured to program the state-programmable memory element to a predetermined state based on an initialization signal provided to the initialization circuit.

Example 18 is the programmable delay circuit of example 17, wherein the initialization circuit includes a logic-NOR gate, wherein the input node is connected to a first NOR input of the logic-NOR gate, wherein a second NOR input of the logic-NOR gate is configured to receive the initialization signal, and wherein an output result of the logic-NOR gate is connected to the adjustable delay circuit, wherein the output result includes a logic-NOR operation of the first NOR input with the second NOR input.

Example 19 is the programmable delay circuit of any one of examples 17 to 18, wherein the predetermined state includes one of the first state or the second state.

Example 20 is the programmable delay circuit of any one of examples 17 to 19, wherein the initialization circuit is further configured to program the state-programmable memory element to the predetermined state based on the selection signal.

Example 21 is the programmable delay circuit of any one of examples 17 to 20, wherein the initialization circuit includes a first logic-NOR gate and a second logic-NOR gate, wherein the input node is connected to a first input node of the second logic-NOR gate, wherein a second input node of the second logic-NOR gate is configured to receive an output NOR result of the first logic-NOR gate, wherein a first input of the second logic-NOR gate is configured to receive the initialization signal, wherein a second input of the first logic-NOR gate is configured to receive the selection signal, and wherein an output NOR result of the second logic-NOR gate is connected to the adjustable delay circuit.

Example 22 is a programmable delay circuit including an input node, an output node, and a remanent polarizable capacitor coupled to a line that extends from the input node to the output node to cause a variable delay for a signal transmitted via the line from the input node to the output node.

Example 23 is the circuit of example 22, wherein the variable delay is configurable between a first delay and a second delay that depends on a dynamic capacitance of the remanent polarizable capacitor, wherein the first delay is associated with a first dynamic capacitance of the remanent polarizable capacitor and a second delay is associated with a second dynamic capacitance of the remanent polarizable capacitor.

Example 24 is the circuit of example 23, wherein the remanent polarizable capacitor is configured to the first dynamic capacitance based on a first remanent polarization state of the remanent polarizable capacitor, wherein the remanent polarizable capacitor is configured to the second dynamic capacitance based on a second remanent polarization state of the remanent polarizable capacitor.

Example 25 a circuit including an input node, an output node, and an adjustable delay circuit configurable to operate in a first mode or a second mode, wherein the first mode provides a first delay for a signal transmitted from the input node to the output node and the second mode provides a second delay for the signal transmitted from the input node to the output node, wherein the adjustable delay circuit includes a remanent polarizable capacitor that is programmable to a positive remanent polarization state or a negative remanent polarization state, wherein the first delay includes a first transition time associated with a first transition of the remanent polarizable capacitor from the positive remanent polarization state to a non-remanent positive polarization state and/or a second transition from the non-remanent positive polarization state to the positive remanent polarization state, wherein the second delay includes a second transition time associated with a third transition of the remanent polarizable capacitor from the negative remanent polarization state to the non-remanent positive polarization state and/or a fourth transition of the remanent polarizable capacitor from the positive remanent polarization state to a non-remanent negative polarization state.

Example 26 is the circuit of example 25, wherein the non-remanent positive polarization state is defined by a positive voltage across the remanent polarizable capacitor sufficient to program the remanent polarizable capacitor to the positive remanent polarization state.

Example 27 is the circuit of example 26, wherein the positive voltage is greater than a positive threshold voltage associated with the positive remanent polarization state of the remanent polarizable capacitor.

Example 28 is the circuit of any one of examples 25 to 27, wherein the non-remanent negative polarization state is defined by a negative voltage across the remanent polarizable capacitor sufficient to program the remanent polarizable capacitor to the negative remanent polarization state.

Example 29 is the circuit of example 28, wherein the negative voltage includes is less than a negative threshold voltage associated with the negative remanent polarization state of the remanent polarizable capacitor.

Example 30 is the circuit of any one of examples 25 to 29, wherein if the adjustable delay circuit is configured to operate in the second mode, the adjustable delay circuit is configured to return to the positive remanent polarization state after the third transition and configured to return to the negative remanent polarization state after the fourth transition.

Example 31 is the circuit of any one of examples 25 to 30, wherein the adjustable delay circuit is configured to select the first mode, or the second mode, based on a mode selection signal.

Example 32 is the circuit of example 31, wherein to operate in the first mode, the mode selection signal is configured to provide zero volts to a capacitor node of the remanent polarizable capacitor, wherein to operate in the second mode, the mode selection signal is configured to provide a variable voltage to the capacitor node as a function of the output voltage.

Example 33 is the circuit of example 32, further includes an additional delay element having an additional delay time, wherein the mode selection signal configured to provide the variable voltage to the capacitor node as the function of the output voltage includes the mode selection signal configured to provide the variable voltage after the additional delay time.

Example 34 is the circuit of any one of examples 32 to 33, wherein the variable voltage is configured to follow the output voltage after the additional delay time.

Example 35 is the circuit of any one of examples 25 to 34, further including an initialization circuit connected between the input node and the adjustable delay circuit configured to program the state-programmable memory element to a predetermined state based on an initialization signal provided to the initialization circuit.

Example 36 is the programmable delay circuit of any one of examples 34 to 35, wherein the predetermined state includes one of the first state or the second state.

Example 37 is the programmable delay circuit of any one of examples 34 to 36, wherein the initialization circuit is further configured to program the state-programmable memory element to the predetermined state based on the selection signal.

Example 38 is the programmable delay circuit of any one of examples 32 to 37, further including an initialization circuit connected between the input node and the adjustable delay circuit configured to program the state-programmable memory element to a predetermined state based on an initialization signal provided to the initialization circuit, wherein the initialization circuit further includes a bypass circuit configured to bypass the initialization circuit based on the mode selection signal.

Example 39 is the programmable delay circuit of example 38, wherein the bypass circuit includes a logic-NOR gate, wherein the mode selection signal is connected to a first input node of the first logic-NOR gate and the initialization signal is connected to a second input of the first logic-NOR gate, wherein an output node of the first logic-NOR gate is connected to a first input node of a second logic-NOR gate, wherein the signal is connected to a second input node of the second logic-NOR gate, and wherein an output node of the second logic-NOR gate is connected to remanent polarizable capacitor.

Example 40 is a method for operating a delay circuit, the method including receiving an input voltage at the delay circuit, receiving a selection signal at the delay circuit, operating a state-programmable memory element in a first delay operation mode or in a second delay operation mode as function of the selection signal, wherein, in the first delay operation mode, the state-programmable memory element has a first dynamic capacitance to provide the input voltage as a first output voltage of the delay circuit with a first delay, and wherein, in the second delay operation mode, the state-programmable memory element has a second dynamic capacitance to provide the input voltage as a second output voltage of the delay circuit with a second delay.

Example 41 is the method of example 40, wherein the first dynamic capacitance is associated with a first transition time for the state-programmable memory element to transition from a first initial state to a first subsequent state, wherein the second dynamic capacitance is associated with a second transition time for the state-programmable memory element to transition from a second initial state to a second subsequent state.

Example 42 is the method of example 41, wherein the first subsequent state is the same as the second subsequent state.

Example 43 is the method of any one of examples 41 to 42, wherein the first initial state includes a positive remanent polarization state and the first subsequent state includes a non-remanent positive polarization state and/or the first initial state includes the non-remanent positive polarization state and the first subsequent state includes the positive remanent polarization state.

Example 44 is the method of any one of examples 41 to 43, wherein the second initial state includes a negative remanent polarization state and the second subsequent state includes a non-remanent positive polarization state and/or a the second initial state includes a positive remanent polarization state and the second subsequent state includes a non-remanent negative polarization state.

Example 45 is the method of any one of examples 40 to 44, further including initializing the state-programmable memory element to a predetermined polarization state before operating the state-programmable memory element.

Example 46 is the method of example 45, wherein the predetermined polarization state includes one of a positive remanent polarization state of the state-programmable memory element or a negative remanent polarization state of the state-programmable memory element.

The terms “at least one” and “one or more” may be understood to include any integer number greater than or equal to one, i.e. one, two, three, four, [...], etc. The term “a plurality” or “a multiplicity” may be understood to include any integer number greater than or equal to two, i.e. two, three, four, five, [...], etc. The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

The term “connected” may be used herein with respect to nodes, terminals, integrated circuit elements, and the like, to mean electrically connected, which may include a direct connection or an indirect connection, wherein an indirect connection may only include additional structures in the current path that do not influence the substantial functioning of the described circuit or device. The term “electrically conductively connected” that is used herein to describe an electrical connection between one or more terminals, nodes, regions, contacts, etc., may be understood as an electrically conductive connection with, for example, ohmic behavior, e.g. provided by a metal or degenerate semiconductor in absence of p-n junctions in the current path. The term “electrically conductively connected” may be also referred to as “galvanically connected”.

While the invention has been particularly shown and described with reference to specific aspects, it should be understood by those skilled in the art that various changes in form and detail may be made therein without departing from the spirit and scope of the invention as defined by the appended claims. The scope of the invention is thus indicated by the appended claims and all changes, which come within the meaning and range of equivalency of the claims, are therefore intended to be embraced.

What is claimed is:

1. A programmable delay circuit comprising:
an input node;
an output node; and
an adjustable delay circuit comprising a state-programmable memory element, wherein the adjustable delay circuit is connected between the input node and the output node and configured to provide an adjustable delay for a signal transmitted from the input node to the output node, wherein if the state-programmable memory element is programmed to a first state, the adjustable delay is a first delay and if the state-programmable memory element is programmed to a second state, the adjustable delay is a second delay.

2. The programmable delay circuit of claim 1, wherein the first delay comprises a first transition time for the state-programmable memory element to transition from the first state to a subsequent state, wherein the second delay comprises a second transition time for the state-programmable memory element to transition from the second state to the subsequent state.

3. The programmable delay circuit of claim 2, wherein the first transition time is different from the second transition time.

4. The programmable delay circuit of claim 1, wherein the state-programmable memory element comprises a remanent polarizable capacitor.

5. The programmable delay circuit of claim 4 wherein the first state of the state-programmable memory element is defined by a first remanent polarization state of the remanent polarizable capacitor, wherein the second state of the state-programmable memory element is defined by a second remanent polarization state of the remanent polarizable capacitor, and wherein the subsequent state of the state-programmable memory element is defined by a further polarization state of the remanent polarizable capacitor.

6. The programmable delay circuit of claim 5, wherein the further polarization state comprises a non-remanent polarization state of the remanent polarizable capacitor defined by a non-zero voltage across the remanent polarizable capacitor.

7. The programmable delay circuit of claim 1, wherein the state-programmable memory element comprises a remanent polarizable capacitor that is programmable to two distinct remanent polarization states as a function of a voltage across the remanent polarizable capacitor.

8. The programmable delay circuit of claim 7, wherein the first state or the second state comprises one of the two distinct remanent polarization states.

9. The programmable delay circuit of claim 1, wherein the adjustable delay circuit is configured to program the state-programmable memory element to the first state or the second state based on a control signal provided to the adjustable delay circuit from a control circuit.

10. The programmable delay circuit of claim 9, wherein the control signal is based on an output voltage at the output node.

11. The programmable delay circuit of claim 9, wherein the control circuit further comprises an additional delay element having an additional delay time, wherein the control circuit is configured to provide the control signal to the adjustable delay circuit after the additional delay time.

12. The programmable delay circuit of claim 1, further comprising an initialization circuit connected between the input node and the adjustable delay circuit configured to program the state-programmable memory element to a predetermined state based on an initialization signal provided to the initialization circuit.

13. The programmable delay circuit of claim 12, wherein the predetermined state comprises one of the first state or the second state.

14. A programmable delay circuit comprising:
an input node;
an output node; and
a remanent polarizable capacitor coupled to a line that extends from the input node to the output node to cause a variable delay for a signal transmitted via the line from the input node to the output node.

15. The circuit of claim 14, wherein the variable delay is configurable between a first delay and a second delay that depends on a dynamic capacitance of the remanent polarizable capacitor, wherein the first delay is associated with a first dynamic capacitance of the remanent polarizable capacitor and a second delay is associated with a second dynamic capacitance of the remanent polarizable capacitor.

16. The circuit of claim 15, wherein the remanent polarizable capacitor is configured to the first dynamic capacitance based on a first remanent polarization state of the remanent polarizable capacitor, wherein the remanent polarizable capacitor is configured to the second dynamic capacitance based on a second remanent polarization state of the remanent polarizable capacitor.

17. A method for operating a delay circuit, the method comprising receiving an input voltage at the delay circuit;
receiving a selection signal at the delay circuit; and
operating a state-programmable memory element in a first delay operation mode or in a second delay operation mode as function of the selection signal,
wherein, in the first delay operation mode, the state-programmable memory element has a first dynamic capacitance to provide the input voltage as a first output voltage of the delay circuit with a first delay, and
wherein, in the second delay operation mode, the state-programmable memory element has a second dynamic capacitance to provide the input voltage as a second output voltage of the delay circuit with a second delay.

18. The method of claim 17, wherein the first dynamic capacitance is associated with a first transition time for the state-programmable memory element to transition from a first initial state to a first subsequent state, wherein the second dynamic capacitance is associated with a second transition time for the state-programmable memory element to transition from a second initial state to a second subsequent state.

19. The method of claim 18, wherein the first initial state comprises a positive remanent polarization state and the first subsequent state comprises a non-remanent positive polarization state and/or the first initial state comprises the non-remanent positive polarization state and the first subsequent state comprises the positive remanent polarization state.

20. The method of claim 17, wherein the second initial state comprises a negative remanent polarization state and the second subsequent state comprises a non-remanent positive polarization state and/or the second initial state comprises a positive remanent polarization state and the second subsequent state comprises a non-remanent negative polarization state.
